(19) United States
(12) Patent Application Publication
(10) Pub. No.: US 2019/0035998 A1
(43) Pub. Date: Jan. 31, 2019

(54) ELECTRICAL CONNECTOR FOR CONNECTING THERMOELECTRIC ELEMENTS AND ABSORBING THE STRESS THEREOF

(71) Applicant: Valeo Systemes Thermiques, Le Mesnil Saint Denis (FR)

(72) Inventor: Cédric De Vaulx, Le Mesnil Saint Denis (FR)

(73) Assignee: Valeo Systemes Thermiques, Le Mesnil Saint Denis (FR)

(21) Appl. No.: 15/779,808

(22) PCT Filed: Nov. 30, 2016
(86) PCT No.: PCT/EP2016/079316

§ 371 Date: Oct. 12, 2018

(30) Foreign Application Priority Data
Nov. 30, 2015 (FR) 1561572

(51) Int. Cl. H01L 35/34; H01L 35/32; H01L 35/08; H01L 35/10

(52) U.S. Cl. CPC H01L 35/34; H01L 35/10; H01L 35/08; H01L 35/32

(57) ABSTRACT

Electrical connector (13) configured for connecting two same outer faces (8) of a first thermoelectric element (4) and of a second thermoelectric element (5), said two thermoelectric elements (4, 5) each consisting of a ring having an outer periphery forming the outer face (8) and an inner periphery forming an inner face (9), and being arranged side by side in the same plane P.

### TECHNICAL FIELD

The invention relates to an electrical connector connecting two thermoelectric elements, and a thermoelectric device equipped with these electrical connectors. It also relates to a method for assembling such a thermoelectric device, as well as a thermoelectric generator, notably one intended to generate an electric current in an automotive vehicle, comprising this thermoelectric device.

### PRIOR ART

In the automotive field, thermoelectric devices using elements called thermoelectric elements have already been proposed, for generating an electric current in the presence of a thermal gradient between two of their opposed faces, called active faces, by the phenomenon known as the Seebeck effect. These devices comprise a first circuit, intended for the circulation of the exhaust gases of an engine, and a second circuit, intended for the circulation of a heat transfer fluid of a cooling circuit. The thermoelectric elements are arranged between the first and the second circuit so as to be subjected to a thermal gradient due to the temperature difference between the hot exhaust gases and the cold coolant fluid.

The thermoelectric elements are grouped in pairs and interconnected by electrical connectors arranged on the active faces of the thermoelectric elements in order to transmit electricity from an active face of one thermoelectric element to an active face of another thermoelectric element.

A distinction is conventionally made between thermoelectric elements of parallelepipedal and ring-shaped geometrical form.

For a thermoelectric device comprising parallelepipedal thermoelectric elements, the hot gas passes through the channel of a flat stainless steel tube. The tube exchanges heat with an active face of the thermoelectric elements, the opposed active faces being in contact with a cold source. The connections between the thermoelectric elements are made alternately between the opposed active faces, by means of flat conducting tracks which may be brazed or glued.

For a thermoelectric device comprising ring-shaped thermoelectric elements superimposed to form a column, the cold water flows within a tube passing through the column, and is therefore in contact with the inner active faces of the rings, while the hot gas is directed along the outside of the column and is therefore in contact with the outer active faces of the rings. This configuration enables the heat transfers to be balanced on the cold and hot sides. In fact, with such a configuration, the heat exchange surface area on the hot side is larger, because the outer active faces are logically larger than the inner active faces, which improves the heat transfer to the rings, given that the exchange coefficient on the hot gas side is lower than on the cold liquid side. In the same column, the connections between the rings are made alternately via the inner active faces and then via the outer active faces of the rings, by means of tubular conductive links, coaxial with the column, acting as metal electrodes, and also brazed onto the active faces of the rings.

The ring-shaped geometry is preferred to the parallelepipedal geometry in terms of thermal efficiency, as explained above.

There is a known way of assembling thermoelectric elements onto the electrical connecting means (tracks or electrodes) by a brazing method. This procedure has the advantage of minimizing the electrical and thermal contact resistance between the thermoelectric elements and the electrical connecting means. However, this means that the whole assembly must be brought to the brazing temperature of about 600° C., resulting in differential expansion effects between the different parts of the assembly, notably between the thermoelectric elements of different types (P or N for example, as explained below in the description), and between the electrical connecting means and the thermoelectric elements. If the parts are not all correctly in contact, because of their different dimensional variations, when the brazing temperature is reached, the joints between the different parts of the assembly may be defective.

One problem therefore arises from the fact that the electrical connecting means and the thermoelectric elements do not all have the same coefficient of thermal expansion. The electrical connecting means therefore contract more than the thermoelectric elements during cooling, which runs the risk of damaging the thermoelectric elements, notably by creating cracks and/or fractures in their contact faces.

This risk is also present when the thermoelectric module is subjected, when in use, to a high temperature difference between its cold and hot side, which is typically the case when the hot face of the device is subjected to temperatures above 250° C. On reaching these temperatures, the electrical connecting means fixed to the thermoelectric elements on the hot side expand more than those fixed to the thermoelectric elements on the cold side, which runs the risk of damaging the thermoelectric elements in the same way as described above.

For devices comprising parallelepipedal thermoelectric elements, there are deformable stress-absorbing elements which are inserted between the thermoelectric element and the electrical connecting means and which can follow the deformation of both of these while providing a thermal link. However, these stress-absorbing elements are difficult to transfer to a ring-shaped geometry of the thermoelectric elements.

The invention is intended to improve the situation.

### BRIEF DESCRIPTION OF THE INVENTION

The object of the present invention is to propose a solution for absorbing the differential expansion stresses that are present between the thermoelectric elements of different types (P and N, for example) and between the thermoelectric elements and the electrical connecting means, for thermoelectric elements having a ring-shaped geometry, without thereby reducing the density of thermoelectric materials.

This object is achieved by means of an electrical connector configured to connect two same outer faces of a first thermoelectric element and of a second thermoelectric element, said two thermoelectric elements each consisting of a ring having an outer periphery forming the outer face and an inner periphery forming an inner face, and being arranged side by side in the same plane P.

Up to the present time, ring-shaped thermoelectric elements have been superimposed to create thermoelectric columns parallel to one another, as explained above. The electrical connection between the outer faces of the thermoelectric elements is always made between two superimposed thermoelectric elements belonging to the same column, that is to say along the axis of the column. The same applies to the electrical connection between the inner faces of the thermoelectric elements, which is made along the axis of the column. The inner and outer faces form the active faces of the thermoelectric elements.

In the present invention, the novelty arises from the fact that the electrical connector connects two ring-shaped thermoelectric elements which are not superimposed, but arranged side by side in the same plane, and which therefore belong to two different columns. Therefore, the electrical connection between the outer faces of the thermoelectric elements is made perpendicularly to the axes of the two columns, instead of parallel to these axes. As for the electrical connection between the inner faces of the thermoelectric elements, this remains unchanged, so that it is between two superimposed thermoelectric elements belonging to the same column, and is thus parallel to the axes of the columns.

This new configuration offers new possibilities for solutions for absorbing differential expansion stresses.

In these circumstances, the electrical connector according to the invention comprises means for absorbing the deformations of the thermoelectric elements. In this case, the connector itself comprises the absorption means in an intrinsic way, instead of using additional elements interleaved between the connector and the thermoelectric elements.

For this purpose, the electrical connector consists of a deformable metal band in the form of a loop surrounding the two thermoelectric elements and mating with the outer faces of the two thermoelectric elements, the band comprising at least one area of adaptation of its length, consisting of the means of absorbing the deformations of the thermoelectric elements.

Because of the invention, when the assembly formed by the electrical connector and the two thermoelectric elements is subjected to large temperature variations, the electrical connector can follow the deformation of each thermoelectric element in an independent way. This is because the electrical connector and the thermoelectric elements contract and expand in a different way. Because of its area of adaptation of its length, the electrical connector changes its shape on the basis of the dimensional variations of the thermoelectric elements, so as to absorb these variations.

By making the deformation of the first thermoelectric element independent of that of the second thermoelectric element, and vice versa, the electrical connector mechanically decouples the contraction and expansion of these elements. The risk of fracture or cracking between the electrical connecting means and the thermoelectric elements is thus limited.

According to a first possible configuration, the electrical connector comprises a first convex portion mating with at least a part of the outer face of the first thermoelectric element, a second convex portion mating with at least a part of the outer face of the second thermoelectric element, and a concave intermediate portion connecting the first to the second portion and forming the area of adaptation of the length of the connector. The depth of the concavity of the convex intermediate portion is variable according to the deformation of the thermoelectric elements.

Thus, as the thermoelectric elements contract, the depth of the concavity of the intermediate portion of the band increases, since the band penetrates to a greater degree between the two thermoelectric elements so as to cover the outer faces as much as possible.

As the thermoelectric elements expand, the depth of the concavity of the intermediate portion of the band decreases, since the band penetrates to a lesser degree between the two thermoelectric elements so as to cover the outer faces to a somewhat lesser extent. The length of the band in its intermediate portion is used in this case to absorb the increase in volume of the thermoelectric elements, rather than to cover the portion of the outer faces that face one another between the thermoelectric elements.

Thus the band operates in the manner of an accordion, being able to fold up when the thermoelectric elements contract and open out when the thermoelectric elements expand. Because of this stress-absorbing intermediate portion, the first portion and the second portion may be deformed independently, to adapt to the specific deformation of each thermoelectric element.

According to one aspect of the invention, the electrical connector has the general shape of a figure of eight. This particular shape of the connector enables the two thermoelectric elements to be decoupled mechanically, while their electrical connection is ensured.

Advantageously, the electrical connector is preferably made of copper, aluminum, or nickel.

The invention mainly relates to an assembly consisting of a first thermoelectric element 4, a second thermoelectric element 5 and an electrical connector 13 as described above.

The invention also relates to a thermoelectric device with a main axis X, comprising at least two thermoelectric columns, each extending parallel to the main axis X, each thermoelectric column having a hollow tubular shape formed by an alignment of ring-shaped thermoelectric elements for generating an electric current by the action of a thermal gradient between their inner faces in contact with a first cold fluid and their outer faces in contact with a second hot fluid, an electrical connection on the cold side being formed in a direction parallel to the axis X between the inner faces of the adjacent thermoelectric elements, arranged in pairs, belonging to the same thermoelectric column. This device is mainly characterized in that a hot side electrical connection is made in a direction perpendicular to the axis X between the outer faces of the adjacent thermoelectric elements, arranged two by two to form pairs, and belonging to two different thermoelectric columns.

The electrical connection between the outer faces of the thermoelectric elements is therefore no longer made within a single column, but between two adjacent columns.

The flow of the current thus takes place from one column to the other on the outer faces of the thermoelectric elements, and also within each column on the inner faces of the thermoelectric elements.

The hot side electrical connection is made, for each pair of thermoelectric elements, by means of an electrical connector as described above, connecting the outer face of a thermoelectric element belonging to a first thermoelectric column to the outer face of a thermoelectric element belonging to a second thermoelectric column.

Optionally, each electrical connector is surrounded by heat exchange fins, preferably designed in copper, aluminum or nickel.

In practice, for each pair of thermoelectric elements, said electrical connector is assembled onto the outer faces of the thermoelectric elements by brazing at a temperature above 500° C.

According to one aspect of the invention, the thermoelectric device comprises electrical insulation means between two adjacent pairs of thermoelectric elements. More precisely, these electrical insulation means consist of an insulating layer, preferably designed in mica. These insulating layers are also in the shape of a figure of eight, to match the shape of the electrical connector. Their function is to prevent electrical short circuits between the pairs of thermoelectric elements.

The invention also relates to a method of assembling a thermoelectric device as described above, comprising the following steps:
for each pair of thermoelectric elements arranged side by side in the same plane P, making an electrical connection between the outer faces of the two thermoelectric elements via an electrical connector brazed onto said outer faces at a temperature above 500° C.;
superimposing the pairs of thermoelectric elements;
inserting an insulating layer between each pair of thermoelectric elements; between the superimposed pairs of thermoelectric elements, forming an electrical connection in a staggered arrangement from one pair to the next between two inner faces of two superimposed thermoelectric elements, by brazing a metal electrode onto said inner faces at a temperature below 300° C.;
inserting two tubes, capable of carrying a cold fluid, into the two openings formed by the inner faces of the superimposed thermoelectric elements;
expanding said tubes to secure the thermoelectric device.

The cold side tubes are preferably made of anodized aluminum.

Finally, the invention relates to a thermoelectric generator, one intended to generate an electric current in an automotive vehicle, comprising at least one thermoelectric device as described above.

Throughout the present description, it should be noted that the terms “ring-shaped” or “ring” are to interpreted as relating to shapes having a central opening. The shapes may or may not be shapes of revolution. The shape of the outer periphery (that is to say the outer face) may be circular or oval or square, etc., as may the shape of the inner periphery (that is to say the inner face) defining the central opening.

### DESCRIPTION OF THE FIGURES

The invention will be better understood and other objects, details, characteristics and advantages thereof will be more fully apparent from the following detailed explanatory description of at least one embodiment of the invention, provided solely by way of purely illustrative and non-limiting example, with reference to the attached schematic drawings.

In these drawings:

FIG. 1 shows a longitudinal section, in perspective, of a thermoelectric device according to the prior art;

FIG. 2 shows three successive sectional views of two thermoelectric elements of different types, subjected to heating and then cooled according to the prior art;

FIG. 3 shows, in perspective, the electrical connector according to the invention;

FIG. 4 is a view from above of FIG. 3;

FIG. 5 shows the assembly of the electrical connector according to the invention with thermoelectric elements;

FIG. 6 is a perspective view of the electrical connector equipped with heat exchange fins;

FIGS. 7 and 8 show other possible shapes of thermoelectric elements suitable for the invention;

FIG. 9 shows the flow of the current within the electrical connector of the invention;

FIG. 10 is an exploded perspective view of the different component parts of a thermoelectric device according to the invention;

FIG. 11 shows, in perspective, an assembled thermoelectric device.

### DETAILED DESCRIPTION

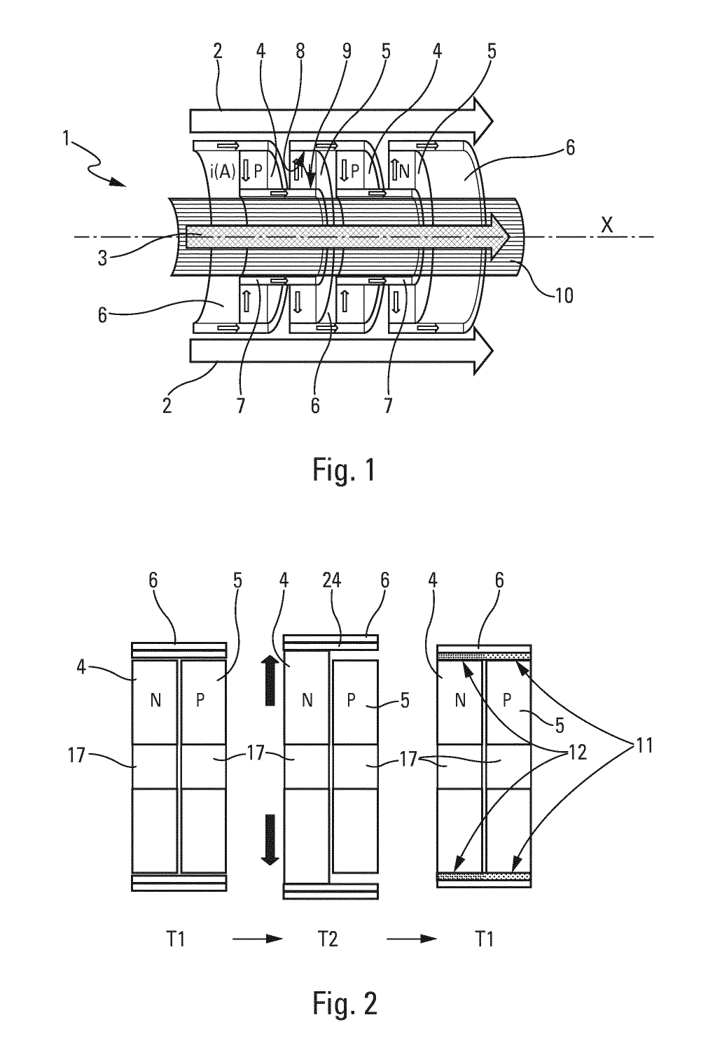

FIG. 1 shows an example of a conventional thermoelectric device 1 according to the prior art.

This device here comprises a first source 2, called the hot source, capable of allowing the flow of a first fluid, notably exhaust gases of an engine, and a second source 3, call the cold source, capable of allowing the flow of a second fluid, notably a heat transfer fluid of a cooling circuit, having a temperature below that of the first fluid.

The device 1 comprises a plurality of thermoelectric elements 4, 5, which are ring-shaped in this case, capable of generating an electric current by the action of a thermal gradient between two of their faces, of which one, 8, called the first active face, is defined by a cylindrical outer peripheral surface, and the other, 9, called the second active face, is defined by a cylindrical inner peripheral surface defining an opening 17. Said first and second faces 8, 9 have circular cross sections, for example. More generally, any rounded and/or polygonal cross section is possible.

Such elements 4, 5 operate according to the Seebeck effect by enabling an electric current to be created in a metal electrode 6, 7 connected between said faces 8, 9 subjected to the thermal gradient. Such elements 4, 5 are made, for example, of bismuth and tellurium (Bi2Te3), as is known to those skilled in the art.

The thermoelectric elements 4, 5 may be, on the one hand, elements 4 of a first type, called P, for establishing an electrical potential difference in a direction called the positive direction when they are subjected to a given thermal gradient, and, on the other hand, elements 5 of a second type, called N, for creating an electrical potential difference in an opposite direction called the negative direction, when they are subjected to the same thermal gradient.

The thermoelectric elements 4, 5 shown in all the figures are each formed by a one-piece ring. However, they may each be formed by a plurality of pieces, each piece forming an angular portion of the ring.

In FIG. 1, said thermoelectric elements 4, 5 are arranged, for example, in the longitudinal extension of one another, notably in a coaxial way; they alternate between P elements and N elements. Notably, their shapes and sizes are identical. However, they may have a thickness, that is to say a dimension between their two flat faces, that differs from one type to another, notably according to their electrical conductivity.

Said thermoelectric elements 4, 5 are, for example, grouped in pairs, each pair being formed by a said P-type thermoelectric element 4 and a said N-type thermoelectric element 5, and said device 1 is configured to allow a flow of current between the first active faces 8 of the thermoelectric elements of the same pair and a flow of current between the second active faces 9 of each of the thermoelectric elements of said same pair and the neighboring thermoelectric element of the neighboring pair. Thus a series flow of electric current is provided between the thermoelectric elements 8, 9 arranged side by side, as shown by the small arrows.

The device of the invention further comprises metal electrodes 6, 7 between the first and second thermoelectric elements 4, 5. These electrodes 6, 7 each take the form of a band with a central axis X. For example, along the direction X, an electrode of a first type 6 is provided in all cases between an N-type thermoelectric element 5 and a P-type thermoelectric element 4. An electrode of a second type 7 is provided in all cases between a P-type thermoelectric element 4 and an N-type thermoelectric element 5.

Said electrodes 6, 7 differ in their diameters. Thus the electrode 6 provided between an N-type thermoelectric element 5 and a P-type thermoelectric element 4 will have a greater diameter than the electrode 7 provided between said P-type thermoelectric element 4 and the next N-type thermoelectric element 5.

In other words, for the thermoelectric device 1 according to the invention, two sets of electrodes 6, 7 of different sizes are required, namely a first electrode for the electrical connection on the cold source side 3 and a second electrode, having a greater diameter, for the hot source side 2.

These conductive connections are usually formed by brazing the electrodes 6, 7 onto the thermoelectric elements 4, 5, using a brazing alloy filler metal 24 as shown in FIG. 2.

Firstly, the electrode 6 is positioned around the thermoelectric elements 4, 5 at ambient temperature T1. The elements 4, 5 and the electrode 6 are coaxial. The whole assembly is brought to the brazing temperature T2 of about 600° C. The thermoelectric elements 4, 5 have different coefficients of expansion, and do not expand in the same way, just like the electrode 6. In this case, the element 4 expands to a markedly greater degree than element 5. The direction of expansion is indicated by the two arrows. When the contact is made between the element 4 and the electrode 6 via the brazing alloy filler metal 24, a gap appears between the element 5 and the electrode 6. This gap makes it impossible to achieve good-quality brazing. If the assembly is cooled to return to the ambient temperature T1, the elements 4, 5 contract, and the resulting assembly has good-quality brazing 12 between the element 4 and the electrode 6 and defective brazing 11 between the element 5 and the electrode 6. The difference in thermal expansion therefore has an effect on the quality of the assembly of a pair of thermoelectric elements 4, 5 by brazing.

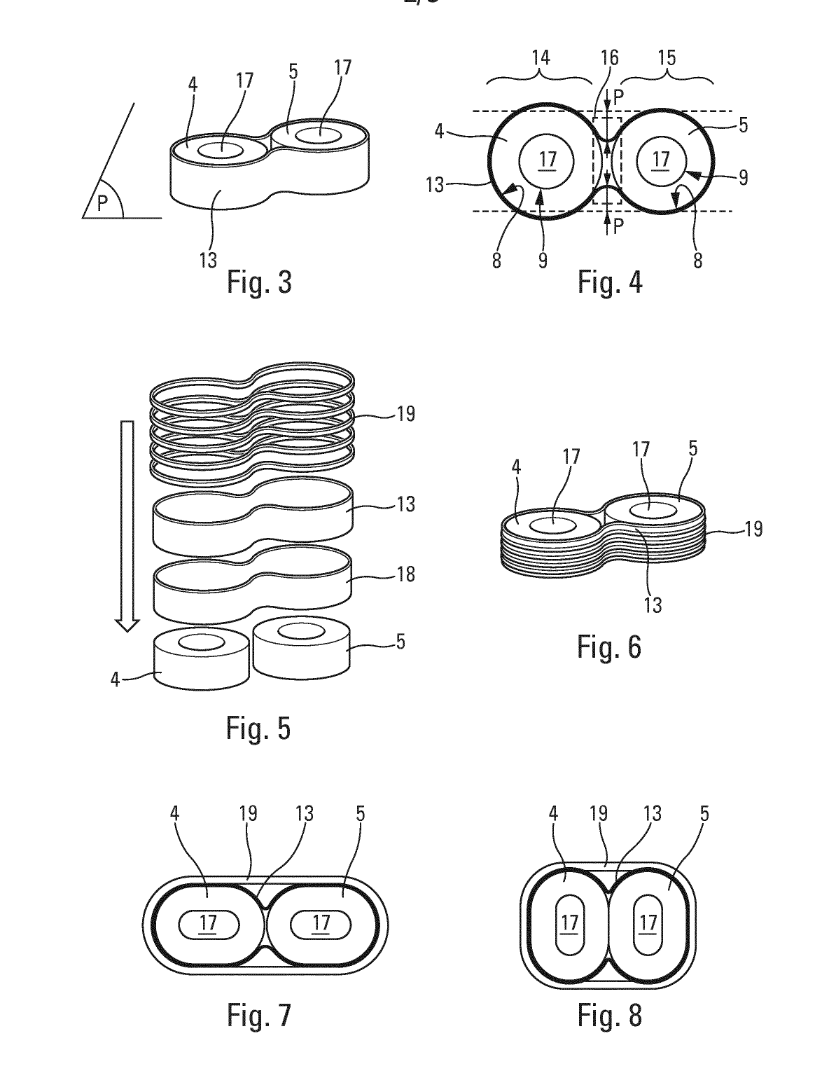

With reference to FIG. 3, an electrical connector 13 according to the invention, in the shape of a figure of eight, may be used to electrically connect two thermoelectric elements 4, 5 which are arranged not coaxially but side by side in the same plane P.

This connector 13 consists of a band 13 in the form of a loop surrounding the two elements 4, 5. The inner wall of the band 13 mates with the outer faces 8 of the elements 4, 5. The width of the band 13 is equivalent to the width of the elements 4, 5.

As shown more fully in FIG. 4, the band 13 is composed of three portions, namely:
a first portion 14 surrounding most of the outer face 8 of the element 4;
a second portion 15 surrounding most of the outer face 8 of the element 5;
an intermediate portion 16 connecting the first portion 14 to the second portion 15.

The shape of the first and second portions 15, 16 is convex, while the shape of the intermediate portion 16 is concave. The band 13 therefore has an undulation or concavity in its intermediate portion 16 at the position of the two portions joining the first to the second portion. This undulation is a “soft” area; that is to say, it enables the band 13 to be made longer or shorter so that it can follow the expansion and contraction of the elements 4, 5 that it surrounds.

More precisely, the depth p of this undulation is variable, because the band 13 can be deformed. The band can thus increase the radius of its convex portions 15, 16 by reducing the depth of the undulation of the intermediate portion 16. Conversely, the band 13 can reduce the radius of its convex portions 15, 16 by increasing the depth of the undulation of the intermediate portion 16.

Additionally, since the elements 4, 5 are not coaxial, the band 13 can follow the expansion and contraction of the elements 4, 5 independently. For example, in FIG. 4 where the elements 4, 5 are subjected to a brazing temperature, the two broken lines clearly show that the element 4 undergoes greater thermal expansion than the element 5. The band 13 follows this expansion in the first portion 14, while the intermediate portion 16 absorbs the stresses generated by this expansion to prevent their transmission to the second portion 15.

The band 13 thus adapts independently to the respective coefficient of expansion of each element 4, 5 by varying the depth p of its intermediate portion 16. In other words, the band 13 absorbs the stresses of differential expansion at the brazing temperature.

Thus the band 13 always remains in contact with the outer faces 8 of the elements 4, 5, regardless of their deformation, and there is no gap that might make the brazing defective.

The band 13 thus allows the mechanical decoupling of the elements 4, 5, while ensuring their electrical connection.

FIG. 5 shows the assembly of the band with the elements 4, 5. In this case, the two elements 4, 5 are arranged side by side on the same plane, and the band 13, preferably made of copper, aluminum or nickel, is then brazed onto the outer faces of the elements 4, 5, using a brazing strip 18 which is also in the shape of a figure of eight. Fins 19, which improve the heat transfer coefficient on the hot side, are preferably added all around the band 13. These fins 19 are also in the shape of a figure of eight in this example. They are preferably designed in aluminum, nickel, or stainless steel.

When all the parts are assembled, the result is the assembly shown in FIG. 6.

For the sake of simplicity, fins 19 may be made in a shape which does not exactly match that of the band 13, as shown in FIGS. 7 and 8.

In these figures, it should also be noted that the elements 4, 5 may have a shape other than that of a circular ring; in this case, they may have an oval form and be arranged side by side with their shorter sides (FIG. 7) or their longer sides (FIG. 8) facing one another.

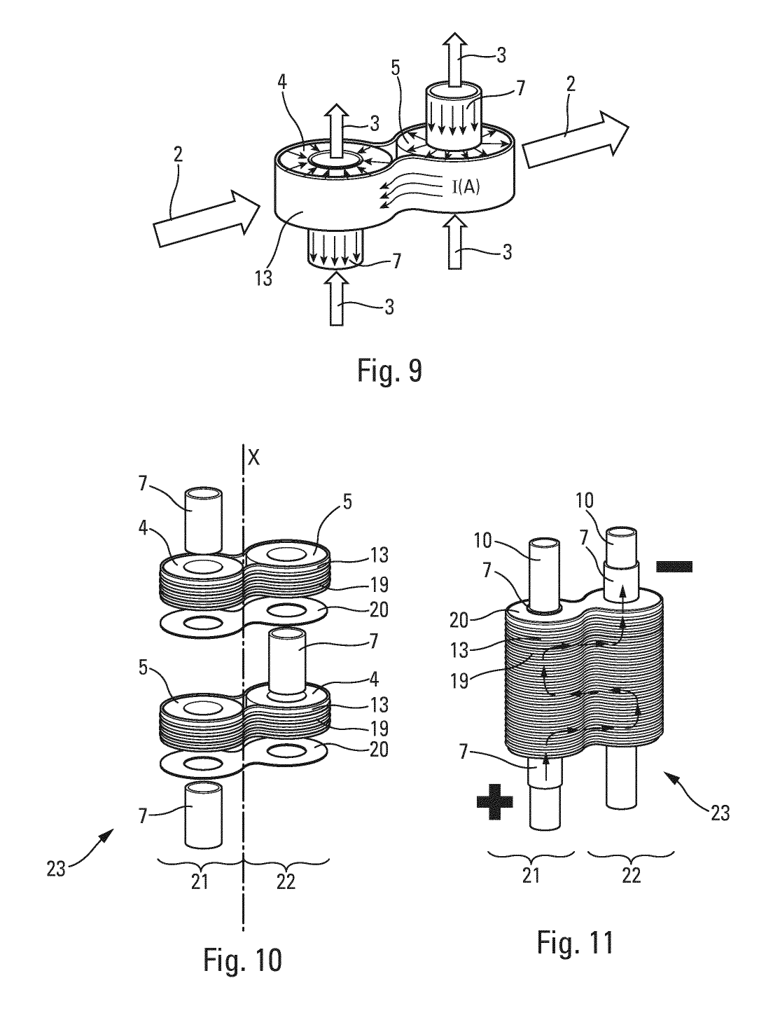

When the band 13 has been assembled onto the elements 4, 5 on the hot side to form a pair, a plurality of pairs must be assembled together on the cold side. For this purpose, conventional electrodes 7 are assembled onto the inner faces of the elements 4, 5 by low-temperature brazing, as illustrated in FIG. 9. The electrode 7 brazed to the element 4 is coaxial with the element 4 and projects from one side so that it can be brazed to another element 5 of an adjacent pair. Similarly, the electrode 7 brazed to the element 5 is coaxial with the element 5 and projects from the other side so that it can be brazed to another element 4 of an adjacent pair. The cold fluid 3 flows in the openings of the electrodes 7 in contact with the inner faces 9 of the elements 4, 5, while the hot fluid 2 flows all around the band 13 in contact with the outer faces 8 of the elements 4, 5.

The temperature difference between the inner faces 9 of the elements 4, 5 in contact with the cold fluid and the outer faces 8 of the elements 4, 5 in contact with the hot fluid creates a flow of current, illustrated by the arrows in FIG. 9. The current therefore flows from the electrode 7 in contact with the element 5 toward the band 13, then toward the element 4 and its electrode 7.

To connect a number of pairs, electrical insulation layers 20 must be added between them, as shown in FIG. 10, to prevent short circuits between the elements 4, 5. These insulating layers 20 are preferably made of mica, and are also in the shape of a figure of eight, to match the general outer shape of the pairs.

The pairs are superimposed on one another, so as to form a thermoelectric device 23 according to the invention, which has a main axis X and is composed of two columns 21, 22.

To enable the current to flow within the thermoelectric device 23, the pairs are inverted relative to one another, so that there is an alternation of elements 4 and elements 5 within the same column 21, 22. The current flow is illustrated by arrows in FIG. 11.

Two tubes 10, in which the cold fluid 3 flows, are inserted into the two openings of the two columns 21, 22. These tubes are preferably made of anodized aluminum and are expanded so as to secure the thermoelectric device 23.

The configurations shown in the cited figures are possible examples only.

As regards the above description, the optimal dimensional relations for the parts of the invention, including variations of size, materials, shapes, functions and modes of operation, assembly and use, are considered to be apparent and evident for those skilled in the art, and any relations equivalent to the material illustrated in the drawings and that described in the statement are considered to be included in the present invention.

1. An assembly formed by:
a first thermoelectric element:
a second thermoelectric element; and
an electrical connector, the electrical connector connecting two same outer faces of the first thermoelectric element and of the second thermoelectric element,
said two thermoelectric elements each consisting of a ring having an outer periphery forming the outer face and an inner periphery forming an inner face, and being arranged side by side in the same plane.

2. The assembly as claimed in claim 1, wherein the connector comprises means for absorbing the deformations of the thermoelectric elements.

3. The assembly as claimed in claim 2, wherein the connector consists of a deformable metal band in the form of a loop surrounding the two thermoelectric elements and mating with the outer faces of the two thermoelectric elements, the band comprising at least one area of adaptation of its length, forming the means of absorbing the deformations of the thermoelectric elements.

4. The assembly as claimed in claim 3, wherein the connector comprises a first convex portion mating with at least a part of the outer face of the first thermoelectric element, a second convex portion mating with at least a part of the outer face of the second thermoelectric element, and a concave intermediate portion connecting the first portion to the second portion and forming the area of adaptation of the length of the connector.

5. The assembly as claimed in claim 4, wherein the depth of the concavity of the convex intermediate portion is variable according to the deformation of the thermoelectric elements.

6. The assembly as claimed in claim 1, wherein the connector is generally shaped in the form of a figure of eight.

7. A thermoelectric device with a main axis, comprising:
at least two thermoelectric columns, each extending parallel to the main axis, each thermoelectric column having a hollow tubular shape formed by an alignment of ring-shaped thermoelectric elements for generating an electric current by the action of a thermal gradient between their inner faces in contact with a first cold fluid and their outer faces in contact with a second hot fluid,
an electrical connection on the cold side being formed in a direction parallel to the main axis between the inner faces of the adjacent thermoelectric elements, arranged two by two, belonging to the same thermoelectric column,
wherein a hot side electrical connection is made in a direction perpendicular to the main axis between the outer faces of the adjacent thermoelectric elements, arranged two by two to form pairs, and belonging to two different thermoelectric columns.

8. The thermoelectric device as claimed in claim 7, wherein the hot side electrical connection is made, for each pair of thermoelectric elements, by the electrical connector, connecting the outer face of a thermoelectric element belonging to a first thermoelectric column to the outer face of a thermoelectric element belonging to a second thermoelectric column.

9. The thermoelectric device as claimed in claim 8, wherein each electrical connector is surrounded by heat exchange fins designed in copper, aluminum or nickel.

10. The thermoelectric device as claimed in claim 8, wherein, for each pair of thermoelectric elements, said electrical connector is assembled onto the outer faces of the thermoelectric elements by brazing at a temperature above 500° C.

11. The thermoelectric device as claimed in claim 7, further comprising electrical insulation means between two adjacent pairs of thermoelectric elements.

12. The thermoelectric device as claimed in claim 11, wherein said electrical insulation means consist of an insulating layer designed in mica.

13. A method of assembling a thermoelectric device as claimed in claim 7, comprising:
for each pair of thermoelectric elements arranged side by side in the same plane P, making an electrical connection between the outer faces of the two thermoelectric elements via an electrical connector brazed onto said outer faces at a temperature above 500° C.;
superimposing the pairs of thermoelectric elements;
inserting an insulating layer between each pair of thermoelectric elements;
between the superimposed pairs of thermoelectric elements, forming an electrical connection in a staggered arrangement from one pair to the next between the two inner faces of two superimposed thermoelectric elements, by brazing a metal electrode onto said inner faces at a temperature below 300° C.;
inserting two tubes, capable of carrying a cold fluid, into the two openings formed by the inner faces of the superimposed thermoelectric elements; and
expanding said tubes.

14. A thermoelectric generator intended to generate an electric current in an automotive vehicle, comprising at least one thermoelectric device as claimed in claim 12.
